(19) United States
(12) Patent Application Publication
(10) Pub. No.: US 2025/0308944 A1
(43) Pub. Date: Oct. 2, 2025

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventors: Naofumi OHASHI, Toyama-shi (JP); Kazuhiro MORIMITSU, Toyama-shi (JP)

(73) Assignee: KOKUSAI ELECTRIC CORPORATION, Tokyo (JP)

(21) Appl. No.: 19/091,035

(22) Filed: Mar. 26, 2025

(30) Foreign Application Priority Data
Mar. 27, 2024 (JP) 2024-051214

(51) Int. Cl. H01L 21/67; H01L 21/687

(52) U.S. Cl. CPC H01L 21/67017; H01L 21/68771

(57) ABSTRACT

A technique is provided including: a housing constituting a standby chamber in which a plurality of substrates is caused to stand by; a support capable of placing each of the plurality of substrates in a vertical direction inside the housing; and a plurality of inert gas suppliers that supplies an inert gas in a direction along a surface of each of the plurality of substrates placed on the support, in which at least one of the plurality of inert gas suppliers supplies the inert gas toward each of the plurality of substrates from a direction different from a direction of another inert gas supplier.

### CROSS-REFERENCE TO RELATED APPLICATION

This application is based upon and claims the benefit of priority from Japanese Patent Application No. 2024-051214, filed on Mar. 27, 2024, the entire contents of which are incorporated herein by reference.

### FIELD

The present disclosure relates to a method of processing a substrate, a method of manufacturing a semiconductor device, a substrate processing apparatus, and a recording medium.

### DESCRIPTION OF THE RELATED ART

As one step of steps of manufacturing a semiconductor device (device), processing of supplying an inert gas to stacked substrates may be performed in a standby chamber between an atmospheric transfer space and a substrate holding space.

### SUMMARY

As described above, in a standby chamber in which a plurality of substrates is caused to stand by, processing may be performed of supplying an inert gas while causing the substrates to stand by.

The present disclosure provides a technique capable of improving cooling efficiency for a substrate in a standby chamber.

According to an embodiment of the present disclosure,
a technique is provided including:
a housing constituting a standby chamber in which a plurality of substrates is caused to stand by;
a support capable of placing each of the plurality of substrates in a vertical direction inside the housing; and
a plurality of inert gas suppliers that supplies an inert gas in a direction along a surface of each of the plurality of substrates placed on the support, in which
at least one of the plurality of inert gas suppliers supplies the inert gas toward each of the plurality of substrates from a direction different from a direction of another inert gas supplier.

### BRIEF DESCRIPTION OF THE DRAWINGS

FIG. 1 is an explanatory diagram illustrating a schematic configuration example of a substrate processing apparatus according to an embodiment of the present disclosure.

FIG. 2A is a side sectional view illustrating an example of an inert gas supplier according to the embodiment of the present disclosure. FIG. 2B is a top view illustrating an example of the inert gas supplier according to the embodiment of the present disclosure.

FIG. 3 is a block diagram for describing a configuration of a controller of the substrate processing apparatus according to the embodiment of the present disclosure.

FIGS. 4A and 4B are top views illustrating modified examples of the inert gas supplier according to the embodiment of the present disclosure.

### DETAILED DESCRIPTION

### (1) Configuration of Substrate Processing Apparatus

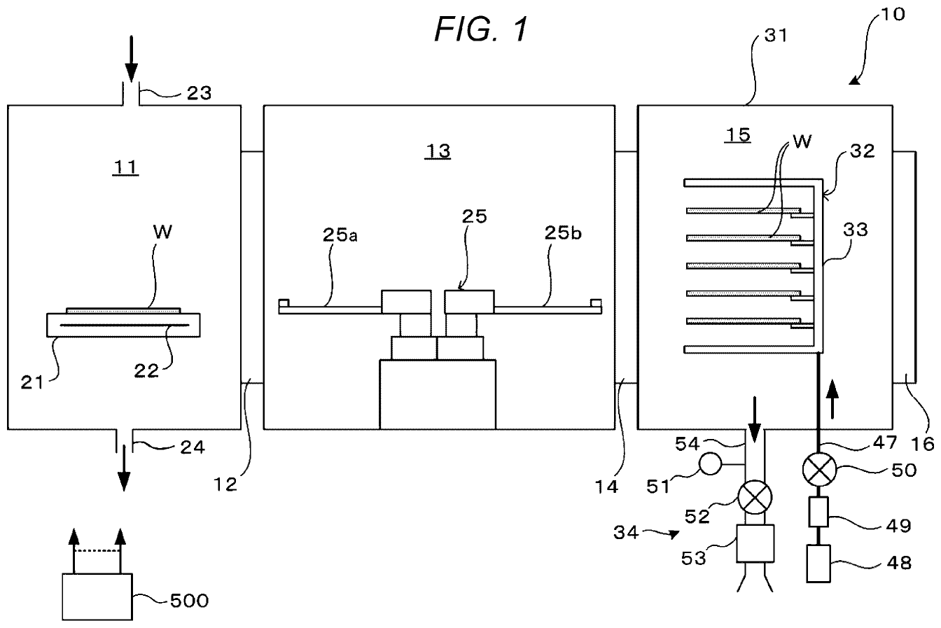

An embodiment of the present disclosure will be described below mainly with reference to FIGS. 1 to 4B. The drawings used in the following description are all schematic, and dimensional relationships between elements, ratios between elements, and the like illustrated in the drawings do not necessarily coincide with actual ones. In addition, dimensional relationships between elements, ratios between elements, and the like do not necessarily coincide with each other between a plurality of drawings. In addition, among the plurality of drawings, substantially the same elements are denoted by the same reference numerals, and the elements will be described in the drawings in which each element first appears, and the description thereof will be omitted in the following drawings unless otherwise necessary. In addition, the present disclosure is not limited to the following embodiments at all, and can be implemented with appropriate modifications within the scope of the present disclosure.

FIG. 1 is a side sectional view illustrating a configuration of a substrate processing apparatus 10. The substrate processing apparatus 10 mainly includes a process chamber 11 in which a wafer W serving as a substrate is processed, a transfer chamber 13 that communicates with the process chamber 11 through a gate valve 12, a load-lock chamber 15 that communicates with the transfer chamber 13 through a gate valve 14, a gate valve 16 that causes the load-lock chamber 15 to communicate with an atmospheric transfer space, and a controller 500 serving as a controller.

The process chamber 11 is provided with a susceptor 21 on which the wafer W is placed, a heater 22 that is provided to be incorporated in the susceptor 21 and heats the wafer W on the susceptor 21, a gas supplier 23 that supplies a processing gas to the wafer W, and an exhauster 24 that exhausts an atmosphere in the process chamber 11. In the process chamber 11, the processing gas supplied from the gas supplier 23 is supplied to the wafer W and exhausted from the exhauster 24, so that predetermined processing is performed on the wafer W.

The transfer chamber 13 is provided with a substrate transfer machine 25 capable of transferring the wafer W. The substrate transfer machine 25 includes arms 25a and 25b on which the wafers W are placed, and is formed to be capable of transferring the wafers W between the process chamber 11 and the load-lock chamber 15 in a sealed vacuum space. The transfer chamber 13 is formed to be capable of withstanding a pressure (negative pressure) less than the atmospheric pressure, such as a vacuum state.

The load-lock chamber 15 is used as a standby chamber in which a plurality of the wafers W is cooled and caused to temporarily stand by. The load-lock chamber 15 is formed by a housing 31. That is, the housing 31 forms the standby chamber in which the plurality of wafers W is caused to stand by. The load-lock chamber 15 forms a load-lock space in which an atmospheric state and a vacuum state are repeated such that the inside of the process chamber 11 does not come into contact with the atmosphere.

The load-lock chamber 15 is provided with a support 32 on which the plurality of wafers W can be placed, inert gas suppliers 33a to 33d (described as an inert gas supplier 33 in FIG. 1) for supplying an inert gas into the load-lock chamber 15, and an exhauster 34 for exhausting an atmosphere in the load-lock chamber 15.

The support 32 is formed to be capable of placing each of the plurality of wafers W in the vertical direction inside the housing 31. The inert gas suppliers 33a to 33d are formed to supply the inert gas in a direction along a surface of each of the plurality of wafers W placed on the support 32.

In the load-lock chamber 15, by the support 32, the plurality of wafers W is aligned in the vertical direction in a horizontal posture and in a state where the centers thereof are aligned with each other, and supported in multiple stages, that is, arranged at intervals. The housing 31 and the support 32 are integrally formed, for example, and include a heat-resistant material, for example, quartz, SiC, or the like.

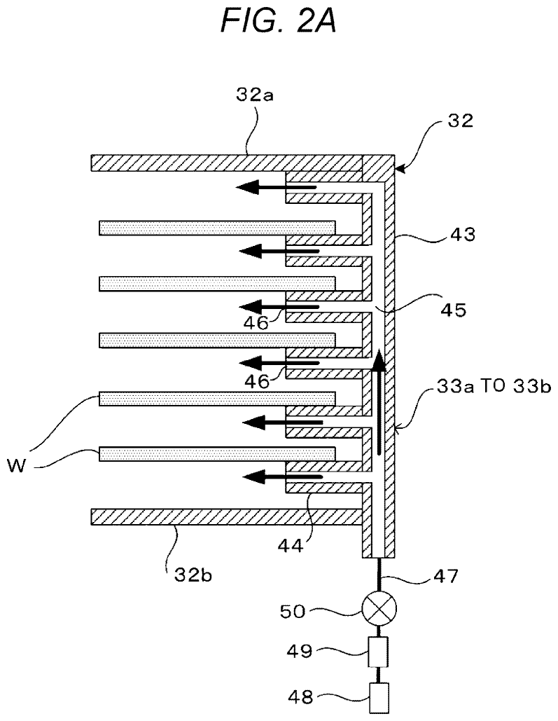

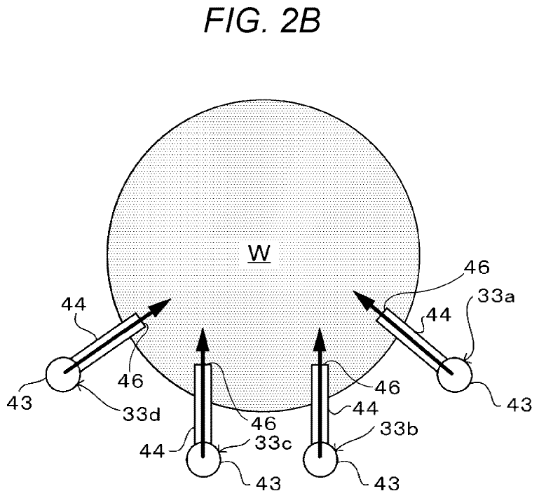

FIGS. 2A and 2B are explanatory diagrams schematically illustrating an example of a schematic configuration of the inert gas suppliers 33a to 33d.

As illustrated in FIG. 2A, the inert gas suppliers 33a to 33d are provided on the support 32 that supports the wafers W, for example. The support 32 includes a plurality of columns 43, a top plate 32a provided at the upper ends of the plurality of columns 43, a bottom plate 32b provided at the lower ends of the plurality of columns 43, and a plurality of holders 44 connected substantially perpendicularly to the plurality of columns 43 and provided substantially horizontally to the top plate 32a and the bottom plate 32b. The plurality of holders 44 is formed to hold the plurality of wafers W substantially horizontally in the vertical direction.

In each of the plurality of columns 43 and the plurality of holders 44, an inert gas flow path 45 is formed. At the tip of each of the plurality of holders 44, an inert gas supply port 46 is formed communicating with the inert gas flow path 45 and supplying the inert gas toward the surface of the wafer W. The inert gas supply port 46 is formed to cause the inert gas flow path 45 and the inside of the load-lock chamber 15 to communicate with each other. The inert gas supply port 46 is disposed between the wafers W. For this reason, the inert gas is supplied in a direction along both the front surface and the back surface of the wafer W.

That is, the inert gas flow path 45 is formed in the vertical direction that is an arrangement direction of the wafers W in the support 32 that supports the wafers W. In other words, the inert gas suppliers 33a to 33d are provided to rise in the arrangement direction of the wafers W from the lower portion to the upper portion in the housing 31, and supply the inert gas substantially horizontally to the surface of the wafer W.

The inert gas flow path 45 of each of the inert gas suppliers 33a to 33d is connected to an inert gas supply pipe 47 for supplying an inert gas. In the inert gas supply pipe 47, an inert gas supply source 48, a mass flow controller (MFC) 49 that is a flow rate control device (flow rate controller), and a valve 50 that is an on-off valve are provided in this order from an upstream direction. Mainly the inert gas suppliers 33a to 33d, the inert gas supply pipe 47, the MFC 49, and the valve 50 constitute an inert gas supply system. The inert gas supply source 48 may be included in the inert gas supply system.

In addition, as illustrated in FIG. 2B, the inert gas suppliers 33a to 33d are disposed around the wafer W in a plan view of the wafer W, and the inert gas suppliers 33b and 33c disposed between the inert gas suppliers 33a and 33d are disposed to supply the inert gas toward the surface of the wafer W substantially in parallel from the same direction. The inert gas suppliers 33a and 33d are disposed to supply the inert gas toward the surface of the wafer W in a direction approximately toward the center of the wafer W from a direction different from the inert gas suppliers 33b and 33c. This disturbs a flow of the inert gas on the surface of the wafer W. As a result, since a temperature distribution of the wafer W is not uniform with respect to a flow from upstream to downstream of inert gas supply, a temperature gradient increases, and a cooling time of the wafer W is shortened. That is, the temperature distribution of the wafer W can be prevented from being distributed along a diameter direction as compared with a case where the inert gas is supplied to the wafer W from one direction. As a result, the cooling time can be shortened, and an amount of the inert gas supplied to the plurality of wafers W in the load-lock chamber 15 can be reduced.

The inert gas suppliers 33a to 33d are not limited to the case illustrated in FIG. 2B. It is sufficient that at least one of the inert gas suppliers 33a to 33d supplies the inert gas toward each of the plurality of wafers W from a direction different from directions of the other inert gas suppliers.

The inert gas supplied from the inert gas supply pipe 47 is supplied into the load-lock chamber 15 through the inert gas flow path 45 and the inert gas supply port 46. The inert gas acts as a purge gas.

The bottom surface of the housing 31 is connected to an exhaust pipe 54 for exhausting the atmosphere in the load-lock chamber 15. The exhaust pipe 54 is formed to exhaust the inert gas supplied into the load-lock chamber 15. This enables the inert gas supplied to the surface of the wafer W to flow without being retained, and it is possible to suppress re-attachment of particles due to, for example, being carried from the process chamber 11 onto the wafer W standby in the load-lock chamber 15. The exhaust pipe 54 may be provided below a side surface of the housing 31 or the like.

The exhaust pipe 54 is connected to a vacuum pump 53 serving as a vacuum exhaust device through a pressure sensor 51 serving as a pressure detecting device (pressure detector) that detects a pressure in the housing 31 and an auto pressure controller (APC) valve 52 serving as a pressure regulating device (pressure regulator). The APC valve 52 is formed to be capable of performing vacuum exhaust of the inside of the housing 31 and stopping the vacuum exhaust by opening and closing a valve thereof in a state where the vacuum pump 53 is operated, and further regulating the pressure in the housing 31 by adjusting a degree of valve opening on the basis of pressure information detected by the pressure sensor 51 in a state where the vacuum pump 53 is operated. Mainly the exhaust pipe 54, the APC valve 52, and the pressure sensor 51 constitute an exhauster 34 (also referred to as an exhaust system). The vacuum pump 53 may be included in the exhauster 34.

In the present disclosure, as an example, a case has been described where the inert gas supply port 46 is provided in each holder 44, the inert gas supply port 46 is provided for each slot (that is, for each wafer), and the inert gas is supplied to the wafers W of the support 32; however, the inert gas may be supplied to the wafers W for every predetermined number of slots (that is, for each predetermined number of wafers) among the plurality of wafers W caused to stand by. For example, the inert gas may be supplied every two slots or every three slots.

### (2) Configuration of Controller

Next, a description will be given of a configuration of the controller 500 serving as a controller (control means).

The controller 500 serving as the controller (control means) controls the components described above to perform a substrate processing step described later.

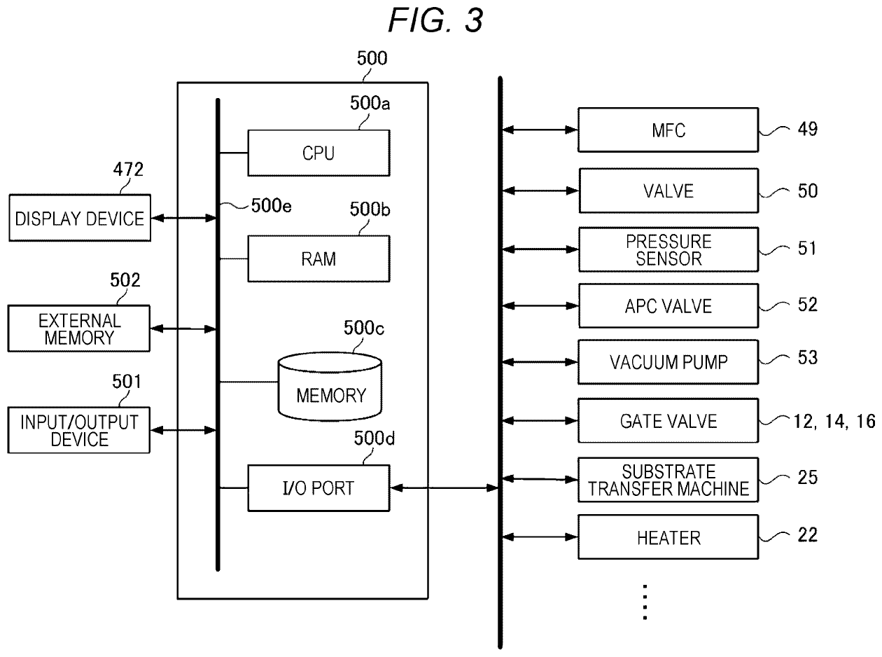

As illustrated in FIG. 3, the controller 500 is configured as a computer including a central processing unit (CPU) 500a, a random access memory (RAM) 500b, a memory 500c, and an I/O port 500d. The RAM 500b, the memory 500c, and the I/O port 500d are capable of exchanging data with the CPU 500a through an internal bus 500e. The controller 500 is connected to an input/output device 501 configured as a touch panel and a display device 472 such as a display, for example.

The memory 500c includes, for example, a flash memory, a hard disk drive (HDD), and the like. The memory 500c readably stores a control program that controls operation of the substrate processing apparatus, a process recipe in which procedures, conditions, and the like of substrate processing described later are described, and the like. Note that the process recipe is a combination of procedures in a substrate processing step to be described later so that the controller 500 can execute the procedures to obtain a predetermined result, and functions as a program. Hereinafter, the process recipe, the control program, and the like will also be collectively and simply referred to as a program. The term “program” in the present description may include only the process recipe alone, only the control program alone, or both of them. In addition, the RAM 500b is configured as a memory area (work area) in which programs, data, and the like read by the CPU 500a are temporarily held.

The I/O port 500d is connected to the MFC 49, the valve 50, the pressure sensor 51, the APC valve 52, the vacuum pump 53, the gate valves 12, 14, and 16, the substrate transfer machine 25, the heater 22, and the like.

The CPU 500a is configured to read the control program from the memory 500c and execute the control program, and to read the process recipe from the memory 500c in response to an input or the like of an operation command from the input/output device 501. Then, the CPU500a is configured to control a wafer W transfer and substrate transfer operation by the substrate transfer machine 25, a supply and discharge operation of the inert gas in the load-lock chamber 15 by the MFC 49, the valve 50, the pressure sensor 51, the APC valve 52, and the vacuum pump 53, a vacuum exhaust operation, a temperature raising and lowering operation by the heater 22 in the process chamber 11, a pressure regulation operation by the APC valve, a gas flow rate regulation operation by the MFC and the valve, and the like according to the content of the read process recipe.

The controller 500 is not limited to a configuration as a dedicated computer, and may be configured as a general-purpose computer. The controller 500 according to the present embodiment can be configured by, for example, preparing an external memory (for example, a magnetic tape, a magnetic disk such as a flexible disk or a hard disk, an optical disk such as a CD or a DVD, a magneto-optical disk such as an MO, or a semiconductor memory such as a USB memory (USB flash drive) or a memory card) 502 storing the above-described program, and installing the program into a general-purpose computer by using the external memory 502. However, the means for supplying the program to the computer is not limited to the case of supplying the program through the external memory 502. For example, the program may be supplied using a communication means such as the Internet or a dedicated line without using the external memory 502. The memory 500c and the external memory 502 are configured as computer-readable recording media. Hereinafter, the memory and the external memory will also be collectively and simply referred to as recording media. In the present description, the term “recording medium” may include only the memory 500c alone, only the external memory 502 alone, or both of them.

### (3) Substrate Processing Step

Next, as one step of steps of manufacturing a semiconductor, a description will be given of processing in the substrate processing apparatus 10 having the above-described configuration. Note that, in the following description, operation of each component constituting the substrate processing apparatus 10 is controlled by the controller 500.

First, the gate valve 16 is opened. Next, the wafer W is loaded into the load-lock chamber 15 through the gate valve 16. The plurality of wafers W is accommodated in the load lock 15. The gate valve 16 is then closed.

Next, vacuum exhaust processing for the load-lock chamber 15 is executed. Specifically, while the inert gas is supplied into the load-lock chamber 15 by control of the valve 50 and the MFC 49, the vacuum exhaust operation is performed by control of the pressure sensor 51, the APC valve 52, and the vacuum pump 53. As a result, the atmosphere having entered the load-lock chamber 15 is discharged as the wafers W are loaded.

When the vacuum exhaust processing ends, the gate valve 14 is opened. Next, only one wafer W accommodated in the load-lock chamber 15 is taken out through the gate valve 14. This take-out processing is performed by the arm 25a or 25b of the substrate transfer machine 25. The gate valve 14 is then closed.

When the take-out processing for the wafer W ends, the gate valve 12 is opened. Next, the first wafer W held by the substrate transfer machine 25 is loaded into the process chamber 11 through the gate valve 12. The gate valve 12 is then closed.

Next, in the process chamber 11, substrate processing is executed on the first wafer W. As a result, a predetermined film is formed on the surface of the first wafer W. While the substrate processing is executed in the process chamber 11, in the transfer chamber 13, the take-out processing for the second wafer W is performed using the arm 25a or 25b of the substrate transfer machine 25.

When the substrate processing ends, the gate valve 12 is opened. Next, replacement processing is performed in which the first wafer W subjected to the substrate processing is unloaded from the process chamber 11 through the gate valve 12, and the second wafer W not subjected to the substrate processing held by the substrate transfer machine 25 is transferred into the process chamber 11.

When the second wafer W is loaded into the process chamber 11, the substrate processing is executed on the second wafer W. In parallel with the substrate processing, return processing for the first wafer W and the take-out processing for the third wafer W are sequentially executed. In the return processing for the first wafer W, first, the gate valve 14 is opened. Next, the first wafer W subjected to the substrate processing is returned to the support 32 of the load-lock chamber 15. This processing is performed by one arm 25a or 25b of the substrate transfer machine 25.

Hereinafter, similarly, each time the substrate processing for each wafer W ends, the replacement processing, the return processing, and the take-out processing are executed. Then, when the substrate processing for all the wafers W supported by the support 32 ends, the gate valve 14 is closed.

Next, cooling processing is executed in a state where the plurality of wafers W is accommodated in the load-lock chamber 15. Specifically, the valve 50 is opened, a flow rate of the inert gas is controlled by the MFC 49, and the inert gas is supplied from each of the inert gas suppliers 33a to 33d to the wafers W in the load-lock chamber 15 through the inert gas flow path 45 and the inert gas supply port 46.

At this time, the controller 500 performs control to reduce the flow rate of the inert gas supplied from the inert gas suppliers 33a to 33d in a case where a preset time elapses after the plurality of wafers W is loaded into the load-lock chamber 15. As a result, a supply amount of the inert gas can be optimized according to a time required for cooling the wafer W.

In addition, at this time, after the plurality of wafers W is loaded into the load-lock chamber 15, the controller 500 performs control to reduce the flow rate of the inert gas supplied from the inert gas suppliers 33a to 33d in a case where a temperature sensor installed in the load-lock chamber 15 is used and temperatures of the plurality of wafers W are less than or equal to a preset temperature. As a result, the supply amount of the inert gas can be optimized according to a temperature of the wafer W.

At this time, conductance of the exhaust pipe 54 is regulated by the vacuum pump 53 and the APC valve 52, so that an exhaust flow rate of the inert gas in the load-lock chamber 15 is controlled, and the inside of the load-lock chamber 15 is maintained at a predetermined pressure. As a result, the inert gas in the load-lock chamber 15 is removed from the load-lock chamber 15 through the exhaust pipe 54.

Then, when a preset time elapses after the plurality of wafers W is loaded into the load-lock chamber 15, or when the temperatures of the plurality of wafers W are less than or equal to the preset temperature, the inside of the load-lock chamber 15 is returned to the atmospheric pressure. Then, the gate valve 16 is opened, and the plurality of processed wafers W is unloaded from the load-lock chamber 15 to the atmospheric transfer space through the gate valve 16.

### Other Embodiments

The embodiment of the present disclosure has been specifically described above, but the present disclosure is not limited to the above-described embodiment, and various modifications can be made without departing from the gist of the present disclosure. A detailed description will be given of only differences between each of the following modified examples and the embodiment described above.

### Modified Example 1

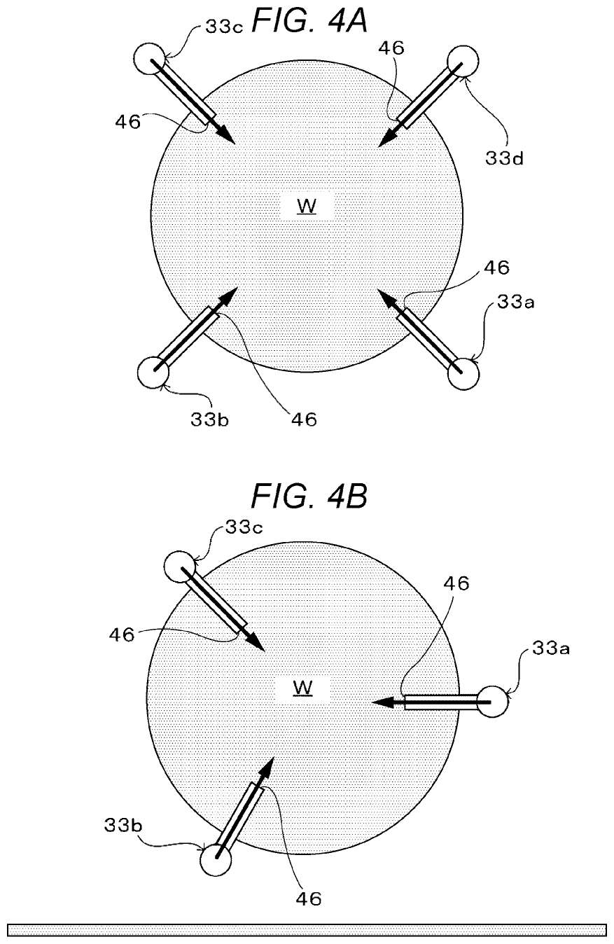

FIG. 4A is a diagram illustrating Modified Example 1 of the inert gas suppliers 33a to 33d described above. In the present modified example, the inert gas suppliers 33a to 33d are disposed at equal intervals around the wafer W, and are formed so that the respective inert gas supply ports 46 face the center of the wafer W, and to supply the inert gas substantially horizontally to the surfaces of the plurality of wafers W. In other words, the inert gas suppliers 33a to 33d are disposed in equal divide with the center of each of the plurality of wafers W interposed therebetween, the inert gas supplier 33a and the inert gas supplier 33c are disposed at positions facing each other with the center of each of the plurality of wafers W interposed therebetween, and the inert gas supplier 33b and the inert gas supplier 33d are disposed at positions facing each other with the center of each of the plurality of wafers W interposed therebetween.

Also in the present modified example, effects can be obtained similar to those in the above-described embodiment. In addition, in the present modified example, further, the inert gas suppliers are disposed at positions facing each other, whereby flows of the respective inert gases collide with each other near the center of the wafer W, and then the inert gases flow to radially diffuse over the entire surface of the wafer W. As a result, the inert gas is supplied even in a range not on an extended line of the inert gas supply port 46, and the cooling time of the wafer W is further shortened, and cooling efficiency can be improved.

### Modified Example 2

FIG. 4B is a diagram illustrating Modified Example 2 of the inert gas suppliers 33a to 33d described above. In the present modified example, the inert gas suppliers 33a to 33c are disposed at equal intervals around the wafer W, and are formed so that the respective inert gas supply ports 46 face the center of the wafer W, and to supply the inert gas substantially horizontally to the surfaces of the plurality of wafers W. In other words, the inert gas suppliers 33a to 33c are disposed in equal divide with the center of each of the plurality of wafers W interposed therebetween.

Also in the present modified example, effects can be obtained similar to those in the above-described embodiment. In addition, in the present modified example, the inert gas suppliers are disposed so that the inert gas is supplied toward the center of each of the plurality of wafers W, whereby flows of the respective inert gases collide with each other near the center of the wafer W, and then the inert gases flow to radially diffuse over the entire surface of the wafer W. As a result, the inert gas is supplied even in a range not on an extended line of the inert gas supply port 46, and the cooling time of the wafer W is further shortened, and cooling efficiency can be improved.

The configuration such as the number and disposition of the inert gas suppliers 33 described in the above embodiment and modified examples is an example, and may be changed according to a situation without departing from the gist.

In addition, the flow of the processing described in the above embodiment is also an example, and an unnecessary step may be deleted, a new step may be added, or the processing order may be changed without departing from the gist.

In the above embodiment, the case has been described where the inert gas flow path 45 and the inert gas supply port 46 are provided in the support 32 and the holder 44 that support the wafer W and used as the inert gas supplier 33, but the present disclosure is not limited to the above-described embodiment. That is, the present disclosure can be applied even in a case where the inert gas supplier 33 is provided separately from the support 32 and the holder 44 that support the wafer W.

It is preferable that recipes used in pieces of processing are individually prepared according to processing contents and stored in the memory 500c through a telecommunication line or the external memory 502. Then, when each piece of processing is started, it is preferable that the CPU 500a appropriately selects an appropriate recipe among the plurality of recipes stored in the memory 500c according to a processing content. As a result, it is possible to form films with various film types, composition ratios, film qualities, and film thicknesses with excellent reproducibility with one substrate processing apparatus. In addition, it is possible to reduce a burden on an operator, and it is possible to quickly start each piece of processing while avoiding an operation error.

The recipe as described above is not limited to a newly created recipe and thus may be prepared, for example, by change in an existing recipe already installed on the substrate processing apparatus. In a case where a recipe is changed, the changed recipe may be installed onto the substrate processing apparatus through a telecommunication line or a recording medium on which the recipe is recorded. In addition, the input/output device 501 in the existing substrate processing apparatus may be operated to directly change an existing recipe already installed on the substrate processing apparatus.

The above-described embodiment has been described using a single wafer type substrate processing apparatus that processes one wafer W at a time. The present disclosure is not limited to the above-described embodiment, and can be suitably applied to, for example, a case of using a batch-type substrate processing apparatus that processes a plurality of wafers W at a time. In the above-described embodiment, the substrate processing apparatus has been described including the cold wall type processing furnace. The present disclosure is not limited to the above-described aspect, and can be suitably applied to a case of using a substrate processing apparatus including a hot wall type processing furnace.

Even in cases where such substrate processing apparatuses are used, each piece of processing can be performed in accordance with processing procedures and processing conditions similar to those in the above-described embodiment and modified examples, so that effects can be obtained similar to those in the above-described embodiment and modified examples.

The above-described embodiment and modified examples may be appropriately combined for use. The processing procedures and processing conditions at that time can be similar to the processing procedures and processing conditions in the above-described embodiment and modified examples, for example.

According to the present disclosure, it is possible to improve cooling efficiency for a substrate in a standby chamber.

What is claimed is:

1. A method of processing a substrate, comprising
Placing a plurality of substrates in a vertical direction; and
supplying an inert gas from at least one inert gas supplier of a plurality of inert gas suppliers toward each of the plurality of substrates placed in a vertical direction from a direction different from a direction of another inert gas supplier, and supplying the inert gas from the another inert gas supplier toward each of the plurality of substrates.

2. The method of claim 1, comprising
the inert gas is supplied to the plurality of substrates in a state where an opening direction of a gas supply port corresponding to the at least one inert gas supplier is different from an opening direction of a gas supply port corresponding to the another inert gas supplier.

3. The method of claim 1, wherein
the inert gas is supplied to the plurality of substrates in a state where at least two inert gas suppliers of the plurality of inert gas suppliers are disposed at positions facing each other with a center of each of the plurality of substrates interposed therebetween.

4. The method of claim 3, comprising
the inert gas is supplied to the plurality of substrates in a state where opening directions of gas supply ports corresponding to the at least two inert gas suppliers are directed to the centers of the substrates.

5. The method of claim 1, wherein the inert gas is supplied to the plurality of substrates in a state where the plurality of inert gas suppliers is disposed in equal divide with a center of each of the plurality of substrates interposed therebetween.

6. The method of claim 1, comprising
the inert gas is supplied to the plurality of substrates in a state where gas supply ports respectively corresponding to the plurality of the gas suppliers are directed toward centers of the substrates.

7. The method of claim 1, wherein
the inert gas is supplied from the plurality of inert gas suppliers to cause a temperature distribution of the plurality of substrates not to be uniform with respect to a flow from upstream to downstream of inert gas supply.

8. The method of claim 1, comprising
the inert gas is supplied to cause inert gases supplied from the plurality of inert gas suppliers to collide with each other on the substrates to be diffused in directions not in extended lines extending in opening directions of gas supply ports respectively corresponding to the plurality of the gas suppliers.

9. The method of claim 1, comprising
the inert gas is supplied from the plurality of inert gas suppliers in a state where each of the gas supply ports respectively corresponding to the plurality of the gas suppliers is disposed between the substrates.

10. The method of claim 1, wherein
the inert gas is supplied from the plurality of inert gas suppliers in a state where a supply amount of the inert gas is controlled in each of the plurality of inert gas suppliers.

11. The of claim 1, comprising
the inert gas is supplied from the gas supply ports respectively corresponding to the plurality of the gas suppliers to each of the substrate supported by a plurality of holders through an inert gas supply flow path provided in each of the holders and in a column connected to each of the holders.

12. The method according to claim 11, wherein
the inert gas is supplied to the plurality of substrates in a state to control amount of the inert gas n the inert gas supply path.

13. The method of claim 1, wherein
the substrates are substrates heated in a process chamber, and
after the substrates are moved from the process chamber to a standby chamber provided with the plurality of inert gas suppliers, the plurality of inert gas suppliers supply the inert gas to the substrates in the standby chamber.

14. The method of claim 13, wherein
in a case where a preset time elapses after the plurality of substrates is loaded into the standby chamber or in a case where temperatures of the plurality of substrates are less than or equal to a preset temperature, a flow rate of the inert gas supplied from the plurality of inert gas suppliers is reduced.

15. The method of claim 1, wherein
the inert gas is supplied from the at least one inert gas supplier along front and back surfaces of the plurality of substrates.

16. The method according to claim 1, wherein
the inert gas is supplied from the another inert gas supplier along front and back surfaces of the plurality of substrates.

17. The method of claim 1, comprising
the inert gas is supplied from gas supply ports respectively corresponding to the plurality of the gas suppliers is provided for every predetermined number of the substrates.

18. A method of manufacturing a semiconductor device, comprising the method of claim 1.

19. A substrate processing apparatus comprising:
a support capable of supporting a plurality of substrates in a vertical direction;
a plurality of inert gas suppliers capable of supplying an inert gas to the plurality of substrates; and
a controller configured to be capable of controlling the inert gas suppliers to supply the inert gas from at least one inert gas supplier of the plurality of inert gas suppliers toward each of the plurality of substrates placed in the vertical direction from a direction different from a direction of another inert gas supplier, and to supply the inert gas from the another inert gas supplier toward each of the plurality of substrates.

20. A non-transitory computer-readable recording medium storing a program that causes, by a computer, a substrate processing apparatus to perform a procedure comprising
providing the substrate; and
supplying an inert gas from at least one inert gas supplier of a plurality of inert gas suppliers toward each of a plurality of substrates placed in a vertical direction from a direction different from a direction of another inert gas supplier, and supplying the inert gas from the another inert gas supplier toward each of the plurality of substrates.
